(19) United States
(12) Patent Application Publication
(10) Pub. No.: US 2011/0059606 A1
(43) Pub. Date: Mar. 10, 2011

(54) METHOD OF MANUFACTURING SEMICONDUCTOR DEVICE AND MASK

(75) Inventor: Fumihiro BEKKU, Kanagawa (JP)

(73) Assignee: RENESAS ELECTRONICS CORPORATION, Kanagawa (JP)

(21) Appl. No.: 12/876,763

(22) Filed: Sep. 7, 2010

(30) Foreign Application Priority Data
Sep. 10, 2009 (JP) 2009-209640

(51) Int. Cl. H01L 21/475; G03F 1/00

(52) U.S. Cl. 438/613; 430/5; 257/E21.488

(57) ABSTRACT

A photosensitive resin film is formed on a protective insulating film. Next, a plurality of bump cores is formed on the protective insulating film along a first straight line by exposing and developing the photosensitive resin film. Next, a plurality of bumps, and a plurality of interconnects that connects each of the plurality of bumps to any of the electrode pads are formed by selectively forming conductive films on a plurality of bump cores, a plurality of electrode pads, and the protective insulating film. In the step of forming a plurality of bump cores, a region bordering on the interconnect on the lateral faces of the bump core is formed to have a gentler slope than that of a region intersecting the first straight line, by exposing the photosensitive resin film only one time using a multi-gradation mask.

The application is based on Japanese patent application No. 2009-209640, the content of which is incorporated hereinto by reference.

### BACKGROUND

1. Technical Field

The present invention relates to a method of manufacturing a semiconductor device having a bump in which a conductive film is formed on a resin-made bump core, and a mask.

2. Related Art

A bump is formed in a semiconductor device in order to mount the semiconductor device on the mounting board. A circuit having the semiconductor device is connected to an electrode such as a land of the mounting board through this bump. In recent years, a technique has been developed in which a core of the bump is formed of a resin, and the bump is formed by forming a conductive film on this core. In this technique, for the purpose of narrowing the bump pitch, and maintaining coatability of the conductive film with respect to the bump core, it is preferable to make the lateral face of the bump core facing an electrode pad side gentler than the other lateral faces thereof.

For example, Japanese Unexamined patent publication NO. 2006-351873 discloses that a second resin layer having a smaller area than that of a first resin layer is formed on the first resin layer, and then when it is heat-treated, the lateral face of the bump core facing the electrode pad side is formed to have a gentler slope than the other lateral faces thereof.

In addition, Japanese Unexamined patent publication NO. 2007-019102 discloses that a first resin portion and a second resin portion smaller than the first resin portion are formed on a protective insulating film, and these two resin portions are unified using flow properties at the time of heat-treatment. Japanese Unexamined patent publication NO. 2007-019102 discloses that when the second resin portion is located at the electrode pad side in the peripheries of the first resin portion, the lateral face of the bump core facing the electrode pad side can be made with a gentler slope than the other lateral faces thereof.

However, in the technique disclosed in Japanese Unexamined patent publication NO. 2006-351873, it is necessary to expose and develop the first resin layer and the second resin layer separately. In this case, position deviation caused by mask deviation is generated between the first resin layer and the second resin layer, and thus there may be a case where the lateral face of the bump core facing the electrode pad side is not able to be formed to have a gentler slope than the other lateral faces thereof.

Further, in the technique disclosed in Japanese Unexamined Patent Publication No. 2007-019102, it is required that a resin for forming the bump core has flow properties at the time of heat-treatment. In this case, the resin for forming the bump core extends, and thus there may be a case where, reversely, it is difficult to narrow the bump pitch.

As seen from the above, it has been difficult to narrow the bump pitch at a high yield ratio in the semiconductor device having a bump in which a conductive film is formed on the resin-made bump core.

### SUMMARY

In one embodiment, there is provided a method of manufacturing a semiconductor device, including: forming a plurality of electrode pads in a substrate; forming a protective insulating film having a plurality of openings located over each of the electrode pads in the plurality of electrode pads and the peripheries thereof; forming a photosensitive resin film over the protective insulating film; forming a plurality of bump cores over the protective insulating film along a first straight line, by exposing and developing the photosensitive resin film; and forming a plurality of bumps, and a plurality of interconnects that connects each of the plurality of bumps to any of the electrode pads, by selectively forming conductive films over the plurality of bump cores, the plurality of electrode pads, and the protective insulating film, wherein in the step of forming the plurality of bump cores, a region bordering on the interconnect on the lateral faces of the bump core is formed to have a gentler slope than a region intersecting the first straight line, by exposing the photosensitive resin film only one time using a multi-gradation mask.

According to the invention, the bump core is formed by exposing the photosensitive resin film. The region bordering on the interconnect on the lateral faces of the bump core is formed to have a gentler slope than that of the region intersecting the first straight line by using the multi-gradation mask in this exposure. For this reason, the exposure may be performed only one time, and an error caused by the mask deviation is not generated. Therefore, it is possible to position a region to be sloped on the lateral faces of the bump core with good accuracy. For this reason, it is possible to make the bump pitch narrow while raising the yield ratio of the semiconductor device.

In another embodiment, there is provided a mask that exposes a photosensitive resin film, and forms bump cores of each of a plurality of bumps, including: a plurality of patterns, provided along a first straight line, for forming the bump cores, wherein the patterns are formed by combination of an entire light-shielding region that shields exposure light and an entire-transmissive region that transmits the exposure light, and wherein the mask further includes a semi-transmissive region that semi-transmits the exposure light, connected to a portion stretched in a direction that does not intersect the first straight line in the boundary of the entire light-shielding region and the entire-transmissive region.

According to the invention, it is possible to narrow the bump pitch while raising the yield ratio of the semiconductor device.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are cross-sectional views illustrating a method of manufacturing a semiconductor device according to a first embodiment;

FIGS. 2A and 2B are cross-sectional views illustrating the method of manufacturing the semiconductor device according to the first embodiment;

FIGS. 3A and 3B are cross-sectional views illustrating the method of manufacturing the semiconductor device according to the first embodiment;

FIG. 4 is a plan view of the semiconductor device in a state of FIG. 3A;

FIG. 5 is a plan view illustrating a configuration of a multi-gradation mask;

FIG. 6 is a plan view of the semiconductor device according to a second embodiment;

FIG. 7 is a cross-sectional view of the semiconductor device according to a third embodiment;

FIG. 8A is a cross-sectional view illustrating a configuration of the semiconductor device according to a fourth embodiment, and FIG. 8B is a plan view illustrating the configuration of the multi-gradation mask used in the fourth embodiment;

FIG. 9 is a plan view of the semiconductor device shown in FIG. 8A;

FIG. 10 is a plan view illustrating the configuration of the semiconductor device according to a fifth embodiment;

FIG. 11 is a plan view illustrating the configuration of the multi-gradation mask used in the fifth embodiment;

FIG. 12 is a plan view illustrating the configuration of the semiconductor device according to a sixth embodiment;

FIG. 13 is a plan view illustrating the configuration of the multi-gradation mask used in the sixth embodiment;

FIG. 14 is a plan view illustrating the configuration of the semiconductor device according to a seventh embodiment; and

FIG. 15 is a plan view illustrating the configuration of a multi-gradation mask used in the seventh embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, the embodiment of the invention will be described with reference to the accompanying drawings. In all the drawings, like elements are referenced by like reference numerals and descriptions thereof will not be repeated.

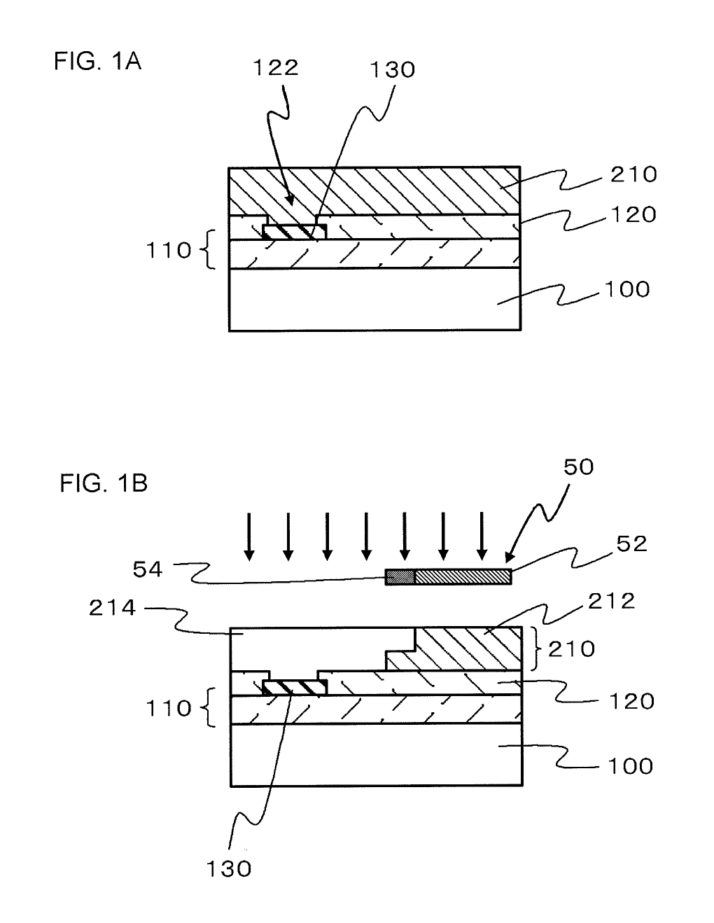

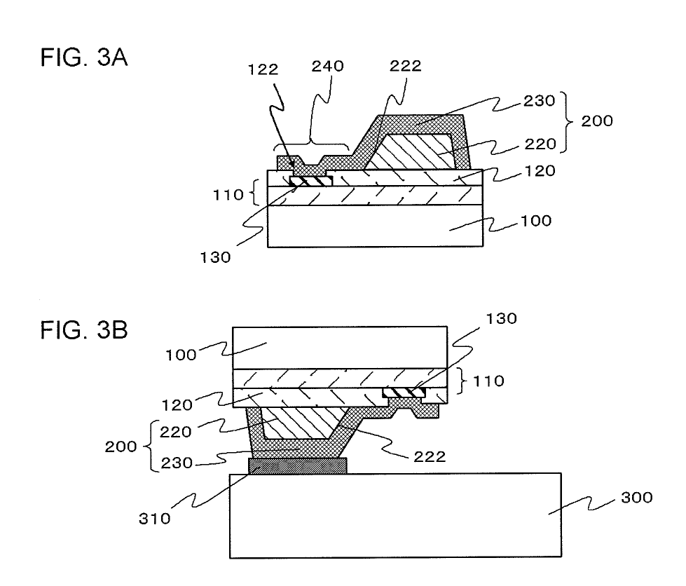

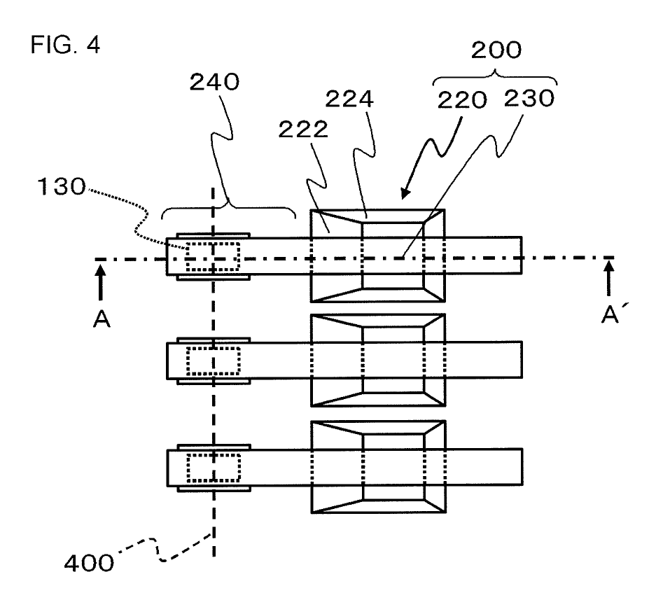

FIGS. 1A and 1B to FIGS. 3A and 3B are cross-sectional view illustrating a method of manufacturing a semiconductor device according to a first embodiment. The method of manufacturing the semiconductor device includes the following processes. First, a plurality of electrode pads 130 is formed on a substrate 100. Next, a protective insulating film 120 is formed at a plurality of electrode pads 130 and the peripheries thereof. The protective insulating film 120 includes a plurality of openings 122. A plurality of openings 122 is respectively located on the electrode pads 130 which are different from one another. That is, each of a plurality of openings 122 is configured so that the electrode pad 130 is located at the bottom thereof. Next, a photosensitive resin film 210 is formed on the protective insulating film 120. Next, a plurality of bump cores 220 is formed on the protective insulating film 120 along a first straight line 400 (shown in FIG. 4; direction extending from the front of paper to the back in FIGS. 1A and 1B to FIGS. 3A and 3B) by exposing and developing the photosensitive resin film 210. Next, a plurality of interconnects 240 (see FIG. 3) for connecting each of a plurality of bumps 200 and a plurality of bumps 200 to any of the electrode pads 130 is formed by selectively forming conductive films on a plurality of bump cores 220, a plurality of electrode pads 130, and the protective insulating film 120. In a process of forming a plurality of bump cores 220, a region 222 bordering on the interconnect 240 among the lateral faces of the bump core 220 is formed to have a gentler slope than that of a region 224 (see FIG. 4) intersecting the first straight line 400 by exposing the photosensitive resin film 210 only one time using a multi-gradation mask 50. The photosensitive resin film 210 has, for example, insulating properties, but may be mixed with conductive particles. Hereinafter, detailed descriptions will be given.

First, as shown in FIG. 1A, elements (not shown), such as a transistor, are formed on the substrate 100, and a multilayered interconnect layer 110 is further formed on the substrate 100. The electrode pad 130 is formed in an interconnect layer located at the uppermost layer of the multilayered interconnect layer 110. Next, the protective insulating film 120 is formed on the multilayered interconnect layer 110. Next, the opening 122 is formed by selectively removing the protective insulating film 120. The opening 122 is located on the electrode pad 130, and exposes the electrode pad 130 from the protective insulating film 120.

Next, the photosensitive resin film 210 is formed on the protective insulating film 120 and the electrode pad 130. The photosensitive resin film 210 is a thermosetting resin such as, for example, a phenol resin, an epoxy resin, a polyimide resin, an amino resin, an unsaturated polyester resin, a silicon resin, or an allyl resin.

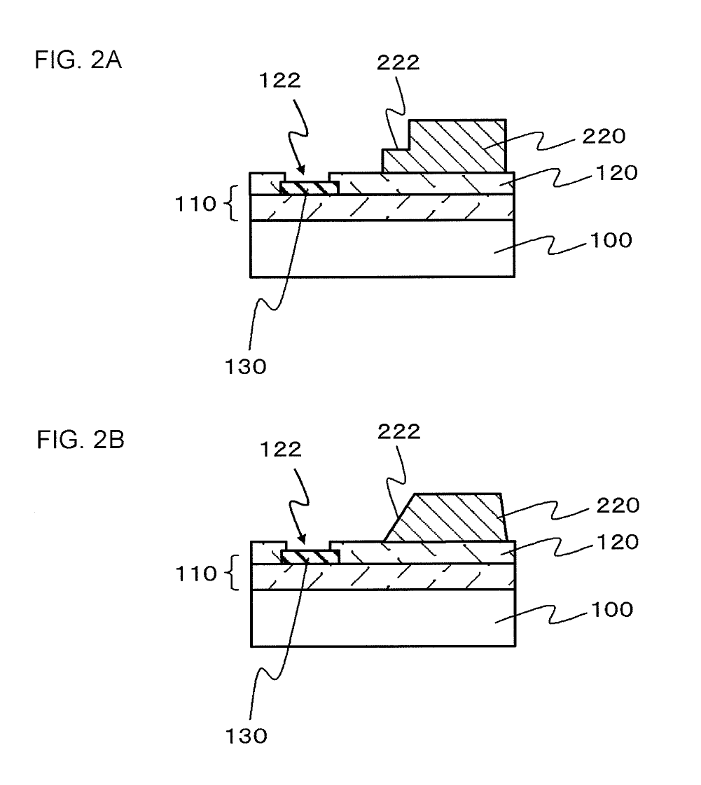

Next, as shown in FIG. 1B, the photosensitive resin film 210 is exposed only one time using the multi-gradation mask 50. Thereby, the photosensitive resin film 210 is exposed except for a region 212 in which the bump core 220 (see FIGS. 2A and 2B) is formed, which results in the formation of an alteration layer 214. When the photosensitive resin film 210 is a positive type, the multi-gradation mask 50 includes an entire light-shielding region 52 that shields exposure light and a semi-transmissive region 54 that semi-transmits exposure light in a region in which the bump core 220 is formed. The semi-transmissive region 54 is provided corresponding to the side in which the interconnect 240 is stretched in the bump core 220. That is, in the multi-gradation mask 50, the amount of light transmission of a region corresponding to the region 222 (see FIGS. 2A and 2B or FIG. 4) bordering on the interconnect on the lateral faces of the bump core 220 is larger than the amount of light transmission of a region corresponding to the region 224 (see FIG. 4) intersecting the first straight line 400 on the lateral faces of the bump core 220. For this reason, a region located below the semi-transmissive region 54 in the photosensitive resin film 210, that is, the side in which the interconnect 240 is stretched in the region 212 for forming the bump core 220 is configured so that the upper layer thereof is formed as the alteration layer 214.

Next, as shown in FIG. 2A, the photosensitive resin film 210 is developed. Thereby, the alteration layer 214 is removed in the photosensitive resin film 210, and the bump core 220 is formed. In this state, the region 222 in which the interconnect 240 is stretched on the lateral faces of the bump core 220 has a substantially stepped shape.

Next, as shown in FIG. 2B, the bump core 220 is cured by heat-treating the bump core 220. In this process, the lateral faces of the bump core 220 are deformed. As described above, in the state before heating, the region 222 (see FIG. 4) bordering on the interconnect 240 on the lateral faces of the bump core 220 is step-shaped. By heat-treating, a portion located close to the surface in resins of the step-shaped region 222 flows, and as a result, the region 222 has a planar shape which is generally sloped. For this reason, the region 222 is formed to have a gentler slope than that of another region in the state after heating.

Next, as shown in FIG. 3A, a conductive film, for example, an Au film is formed on the bump core 220, the protective insulating film 120, and the electrode pad 130 by, for example, a sputtering method. Next, a resist pattern (not shown) is formed on the conductive film, and the conductive film is etched using this resist pattern as a mask. Thereby, the conductive film is selectively removed, and a conductive film 230 for forming the bump 200, and the interconnect 240 are formed. The bump 200 is configured such that the conductive film 230 is formed on the bump core 220. The interconnect 240 is stretched from the conductive film 230 of the bump 200 onto the protective insulating film 120, and connects the bump 200 to the electrode pad 130. After that, the resist pattern is removed.

In this state, the semiconductor device includes the protective insulating film 120, the opening 122 formed in the protective insulating film 120, the electrode pad 130 located at the bottom of the opening 122, the bump 200 formed on the protective insulating film 120, and the interconnect 240. The bump 200 includes the bump core 220 and the conductive film 230. In the bump core 220, the region 222 bordering on the interconnect 240 is formed to have a gentler slope than that of another region, for example, a region intersecting the first straight line 400. The conductive film 230 is formed on at least the upper surface of the bump core 220. The interconnect 240 connects the conductive film 230 of the bump 200 and the electrode pad 130.

After that, as shown in FIG. 3B, the semiconductor device is mounted on the mounting board 300 in a Chip On Glass (COG) manner or a Chip On Film (COF) manner. When the semiconductor device is a liquid crystal driver, the mounting board 300 is a glass substrate or a COF base film. In this state, the bump 200 of the semiconductor device is connected to an electrode 310 of the mounting board 300. The electrode 310 is, for example, a land, but is not limited to the land.

FIG. 4 is a plan view of the semiconductor device in the state of FIG. 3A. Meanwhile, FIG. 3A is a cross-sectional view taken along the line A-A′ of FIG. 4. As shown in FIG. 4, a plurality of bumps 200 is disposed along the first straight line 400 (vertical direction in the drawing). The interconnect 240 is stretched in a second direction different from the first straight line 400, for example, a direction (horizontal direction in the drawing) perpendicular to the first straight line 400. A plurality of bumps 200 is kept away from one another, but is disposed adjacent to one another. In addition, the conductive film 230 of the bump 200 is not formed in a portion in which the above-mentioned first straight line 400 is directed to the stretching direction on the lateral faces of the bump core 220.

The region 222 bordering on the interconnect 240 on the lateral faces of the bump core 220 is formed to have a gentler slope than that of the region 224 intersecting the first straight line 400. In other words, it is possible to make the slope of the region 222 gentle while steeply maintaining the slope of the region 224. Therefore, it is possible to set, for example, a distance between centers of the bump cores 220 lying next to each other to be equal to or less than 50 μm by disposing the bump cores 220 at a narrow pitch along the first straight line 400. In addition, since the slope of the region 222 is gentle, it is possible to suppress the conductive film 230 from being disconnected in the region 222.

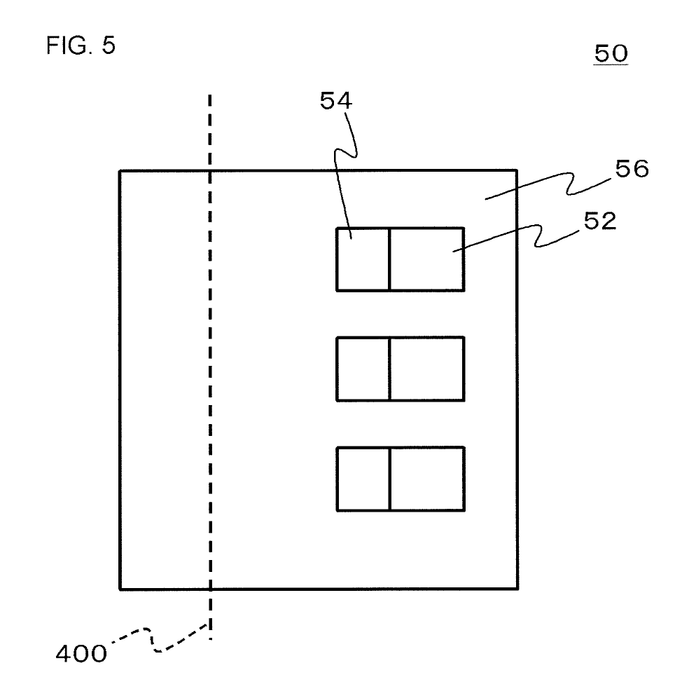

FIG. 5 is a plan view illustrating a configuration of the multi-gradation mask 50. The multi-gradation mask 50 has a plurality of patterns for forming the bump core. A plurality of patterns is provided along the first straight line 400 (vertical direction in the drawing). Each of the patterns is formed by combination of an entire-transmissive region 56 that transmits exposure light and the entire light-shielding region 52 that shields the exposure light. In addition, each of the patterns has the semi-transmissive region 54 that semi-transmits the exposure light. The semi-transmissive region 54 is connected to a portion stretched in a direction which does not intersect the first straight line 400 in the boundary of the entire light-shielding region 52 and the entire-transmissive region 56. In addition, methods of forming the semi-transmissive region 54 include a method of using materials of a light-shielding film different from those of the entire light-shielding region 52, a method of disposing a slit not exceeding the resolution and the like. In the former case, a method of adjusting the amount of light transmission in the semi-transmissive region 54 includes a method of adjusting the film thickness of the light-shielding film in the semi-transmissive region 54. On the other hand, in the latter case, a method of adjusting the amount of light transmission in the semi-transmissive region 54 includes a method of adjusting the density of the slit not exceeding the resolution.

Next, the actions and advantages of the embodiment will be described. According to the embodiment, the bump core 220 is formed by exposing the photosensitive resin film 210 only one time using the multi-gradation mask 50 and then developing it. The multi-gradation mask 50 has the semi-transmissive region 54 in correspondence with the side in which the interconnect 240 is stretched in the bump core 220. For this reason, the region 222 bordering on the interconnect on the lateral faces of the bump core 220 can be formed to have a gentler slope than that of the region 224 intersecting the first straight line 400, without performing the exposure multiple times. Therefore, it is possible to position a region to be sloped on the lateral faces of the bump core 220 with good accuracy. For this reason, it is possible to make the bump pitch narrow while raising the yield ratio of the semiconductor device.

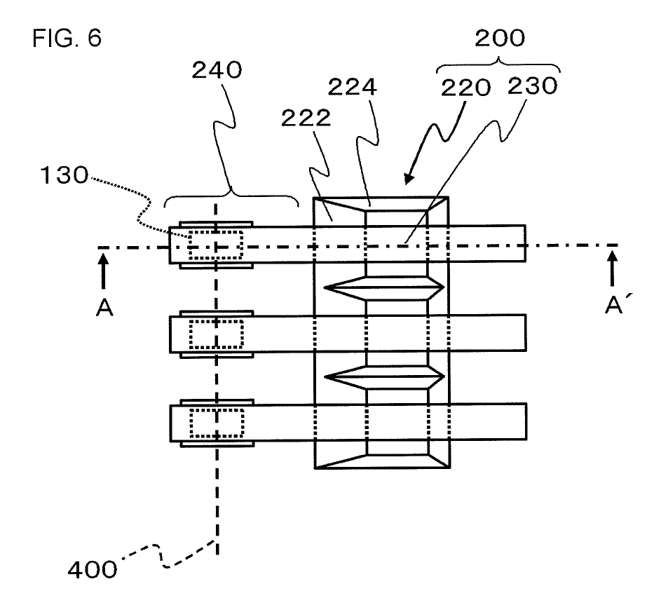

FIG. 6 is a plan view of the semiconductor device according to a second embodiment. This semiconductor device has the same configuration as that of the semiconductor device manufactured by the first embodiment, except that the pitch of the bumps 200 in a direction along the first straight line 400 is narrow, and that the lower portions of the neighboring bump cores 220 are connected to each other, and the cross-sectional view taken along the line A-A′ of FIG. 6 is the same as FIG. 3A. In addition, a method of manufacturing this semiconductor device is also the same as that of the first embodiment.

The same advantages as those of the first embodiment can also be obtained by the embodiment.

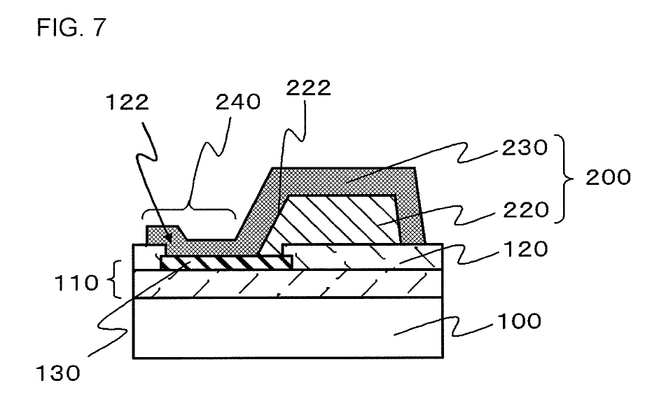

FIG. 7 is a cross-sectional view of the semiconductor device according to a third embodiment. This semiconductor device has the same configuration as that of the semiconductor device according to the first embodiment, except that a portion of the bump core 220 is located on the electrode pad 130. In addition, a method of manufacturing the semiconductor device according to the embodiment is the same as that of the first embodiment.

The same advantages as those of the first embodiment can also be obtained by the embodiment. In addition, a region bordering on the bump 200 in the edges of the opening 122 provided in the protective insulating film 120 is covered by the bump core 220. For this reason, a conductive film including the conductive film 230 and the interconnect 240 does not directly cross the edges of the opening 122, and stretches over the region 222 of the bump core 220 and then stretches over the electrode pad 130 directly. For this reason, the step difference caused by the edges of the opening 122 is prevented from being generated in the conductive film including the conductive film 230 and the interconnect 240. Therefore, it is possible to suppress the conductive film 230 or the interconnect 240 from being disconnected in this portion.

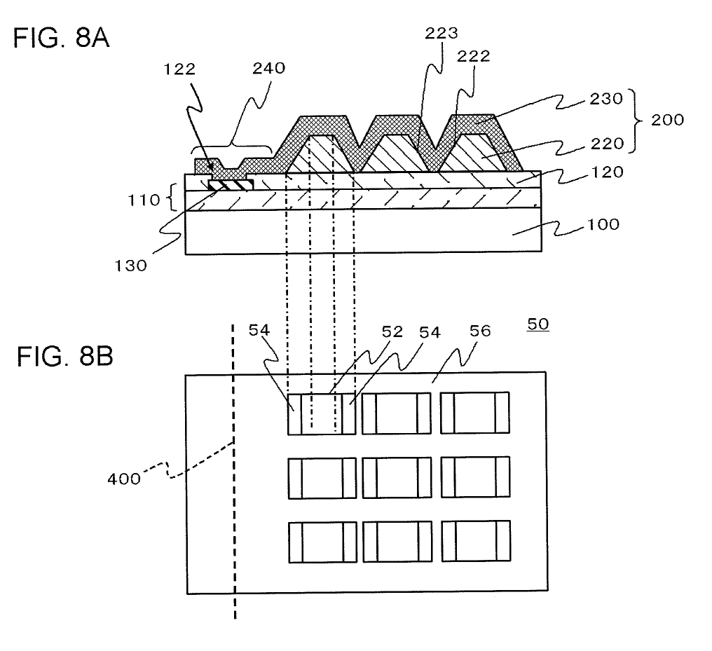

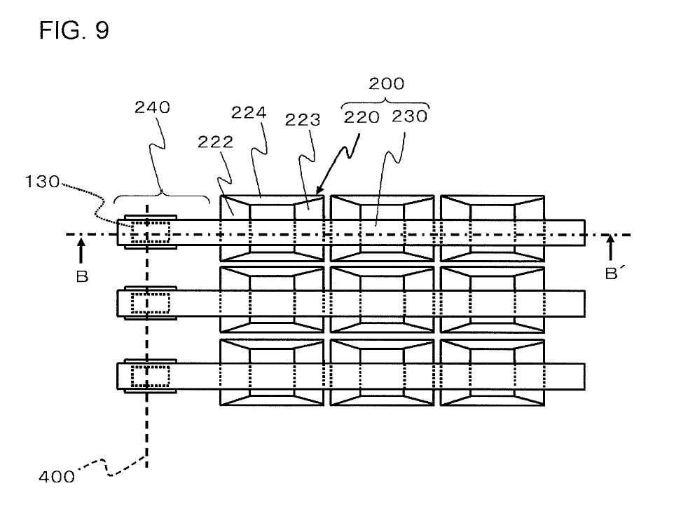

FIG. 8A is a cross-sectional view illustrating a configuration of the semiconductor device according to a fourth embodiment, and FIG. 8B is a plan view illustrating a configuration of the multi-gradation mask 50 used in the manufacture of the semiconductor device of the embodiment. FIG. 9 is a plan view of the semiconductor device shown in FIG. 8A. FIG. 8A is equivalent to a cross-sectional view taken along the line B-B′ of FIG. 9. This semiconductor device has the same configuration as that of the semiconductor device according to the first embodiment, except that a plurality of bumps 200 is provided with respect to one interconnect 240. The size of each of the bumps 200 is smaller than that of the bump 200 according to the first embodiment. That is, in the embodiment, one bump is divided into a plurality of small bumps 200. However, in FIGS. 8A and 8B and FIG. 9, the size of the bump 200 is approximately the same as that in the first embodiment, for the purpose of the description.

A plurality of bumps 200 and the electrode pad 130 are disposed along the same straight line. A plurality of bumps 200 is configured so that the conductive film 230 is integrally formed. That is, the conductive film 230 of a plurality of bumps 200 has an integral interconnect shape, and is formed as an interconnect integral with the interconnect 240. On the lateral faces of the bump core 220, both of the regions 222 and 223 bordering on the conductive film 230 are formed to have a gentler slope than the region 224 intersecting the first straight line 400 (vertical direction in the drawing). In order to form the shape of the bump core 220 in this way, as shown in FIG. 8B, the semi-transmissive region 54 may be added to a portion which corresponds to the region 223 in the multi-gradation mask 50. At this time, the entire light-shielding region 52 overlaps with a region adjacent to the head tip of the bump core 220 and the head tips of the regions 222 and 223, when seen in a plan view. The semi-transmissive region 54 is provided in a portion overlapping with a portion in which the entire light-shielding region 52 is not formed in the regions 222 and 223.

The same advantages as those of the first embodiment can also be obtained in the embodiment. In addition, one bump is divided into a plurality of small bumps 200. For this reason, the volume of a void space located at the periphery of the head portion of the bump core 220 increases with respect to the volume of the head portion thereof. Therefore, when the bump 200 is pressed against the electrode 310 of the mounting board 300 and connected thereto, the degree of freedom of deformation of the bump core 220 increases. For this reason, the adhesion of the bump 200 and the electrode 310 of the mounting board 300 gets better, to thereby allow reliability of the connection of the bump 200 and the electrode 310 to be improved.

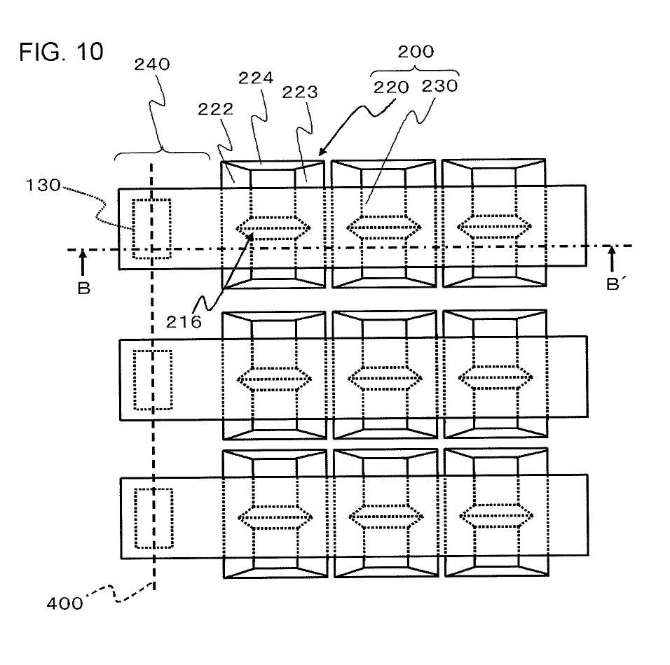

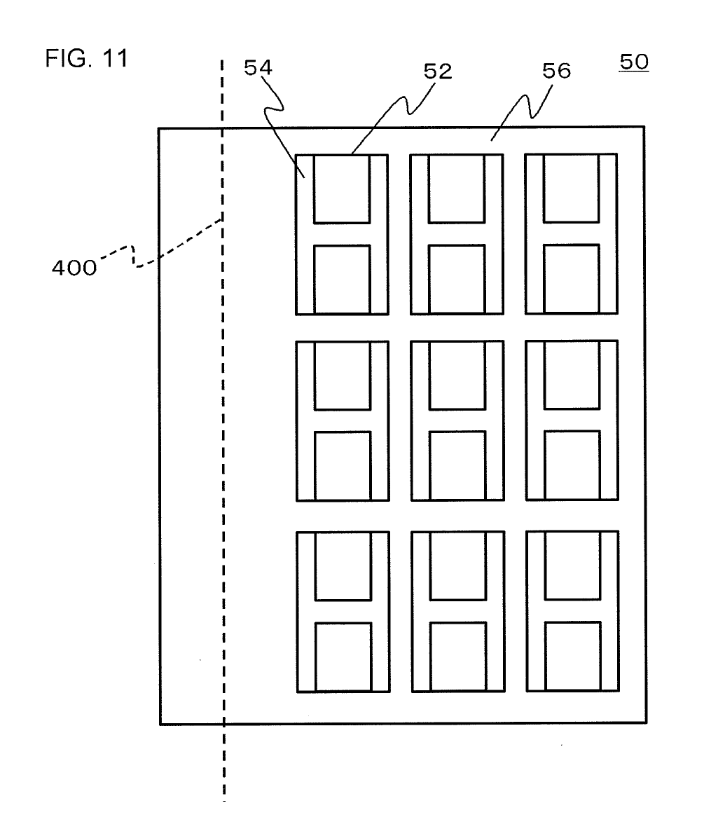

FIG. 10 is a plan view illustrating a configuration of the semiconductor device according to the fifth embodiment. FIG. 11 is a plan view illustrating a configuration of the multi-gradation mask 50 used in the manufacture of the semiconductor device of the embodiment. This semiconductor device has the same configuration as that of the semiconductor device according to the fourth embodiment, except that a groove 216 is formed in the bump core 220 of the bump 200, and the cross-sectional view taken along the line B-B′ of FIG. 10 is the same as FIG. 8A. The groove 216 is stretched substantially in parallel with the direction in which the bumps 200 are lined up. A method of manufacturing this semiconductor device is the same as the method of manufacturing the semiconductor device according to the fourth embodiment, except that the semi-transmissive region 54 is provided in a region corresponding to the groove 216 in the multi-gradation mask 50, as shown in FIG. 11.

The same advantages as those of the fourth embodiment can also be obtained by the embodiment. In addition, since the groove 216 is formed in the bump core 220, the volume of void space located at the periphery of the head portion of the bump core 220 further increases with respect to the volume of the head portion thereof. Therefore, when the bump 200 is pressed against the electrode 310 of the mounting board 300 and connected thereto, it is possible to further increase the deformation amount of the bump core 220.

In addition, the groove 216 is substantially in parallel with the direction in which the bumps 200 are lined up, that is, stretched in the same direction as that of the conductive film 230 of the bump 200. When the conductive film 230 is formed by a gas phase method such as sputtering, coatability of the conductive film 230 is lowered in the boundary division of the bump core 220 and the protective insulating film 120, that is, in the hem portion of the bump core 220. When the groove 216 is not formed, there is a possibility that the region in which this coatability is lowered increases, and resistance of the conductive film 230 increases.

When resistance of the conductive film 230 increases in a portion of the bump 200, the electrical connection between the electrode pad 130 and the bump 200 which is farthest away from the electrode pad 130 is not stabilized. On the other hand, when the groove 216 is stretched in the same direction as that of the conductive film 230 as in the embodiment, the coatability of the conductive film 230 is suppressed from being lowered in a region in which at least the groove 216 is formed. Therefore, it is possible to stabilize the electrical connection between the electrode pad 130 and the bump 200 which is farthest away from the electrode pad 130. In addition, since the conductive film 230 within the groove 216 hardly receives a stress at the time of mounting, it is possible to maintain the electrical connection of each of the bumps 200 by the conductive film 230 within the groove 216, even when the disconnection caused by a stress at the time of mounting is generated in another portion of the conductive film 230. Therefore, it is possible to further raise the reliability of mounting.

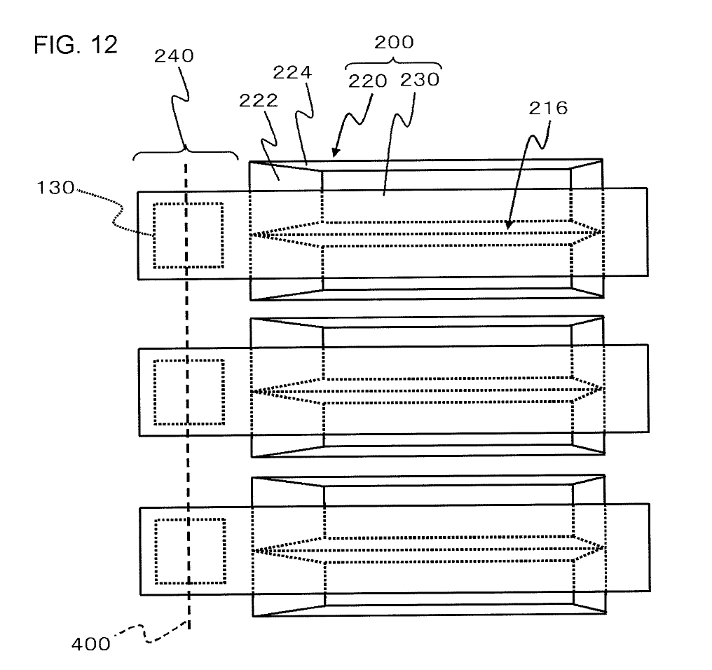

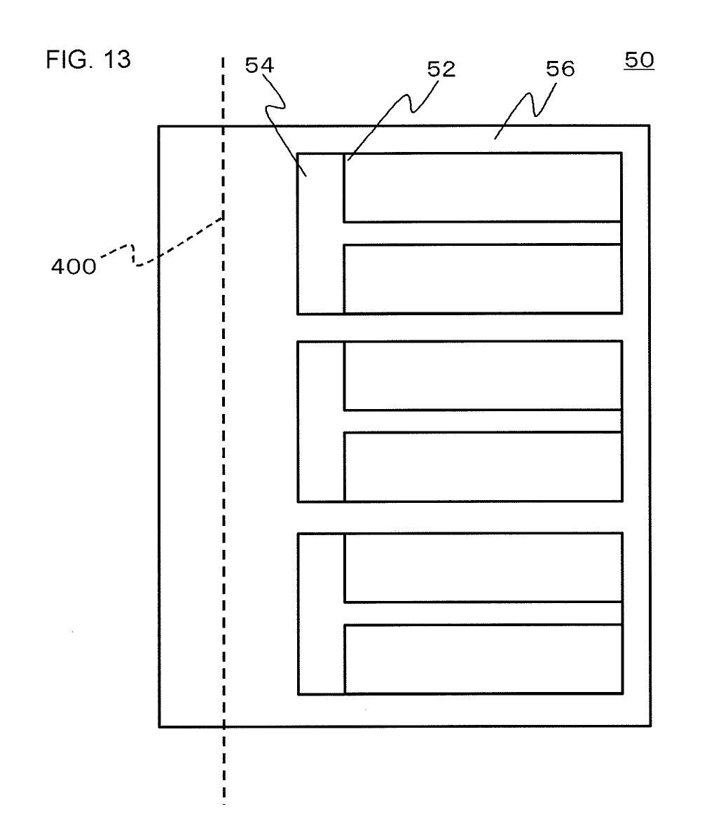

FIG. 12 is a plan view illustrating a configuration of the semiconductor device according to a sixth embodiment. FIG. 13 is a plan view illustrating a configuration of the multi-gradation mask 50 used in the manufacture of the semiconductor device of the embodiment. This semiconductor device has the same configuration as that of the semiconductor device according to the fifth embodiment, except that only one bump 200 is formed with respect to one interconnect 240. That is, this semiconductor device is configured so that the bumps 200 divided into multiple parts in FIG. 10 are unified into one per interconnect 240, and the groove 216 is formed in the bump core 220. The groove 216 is stretched in the same direction as the stretching direction of the interconnect 240. A method of manufacturing this semiconductor device is the same as the method of manufacturing the semiconductor device according to the first embodiment, except that the semi-transmissive region 54 is provided in a region corresponding to the groove 216 in the multi-gradation mask 50, as shown in FIG. 13.

Since the groove 216 is also formed in the bump core 220 in the embodiment, the volume of a void space located at the periphery of the head portion increases with respect to the volume of the head portion of the bump core 220. Therefore, when the bump 200 is pressed against the electrode 310 of the mounting board 300 and is connected thereto, it is possible to increase the deformation amount of the bump core 220. In this case, since adhesion of the bump 200 and the electrode 310 of the mounting board 300 gets better, it is possible to improve reliability of the connection of the bump 200 and the electrode 310. In addition, since the groove 216 is stretched in the same direction as that of the conductive film 230 similarly to the fifth embodiment, coatability of the conductive film 230 is suppressed from being lowered in a region in which at least the groove 216 is formed. Therefore, it is possible to stabilize the electrical connection between the electrode pad 130 and the region which is farthest away from the electrode pad 130 among the bumps 200.

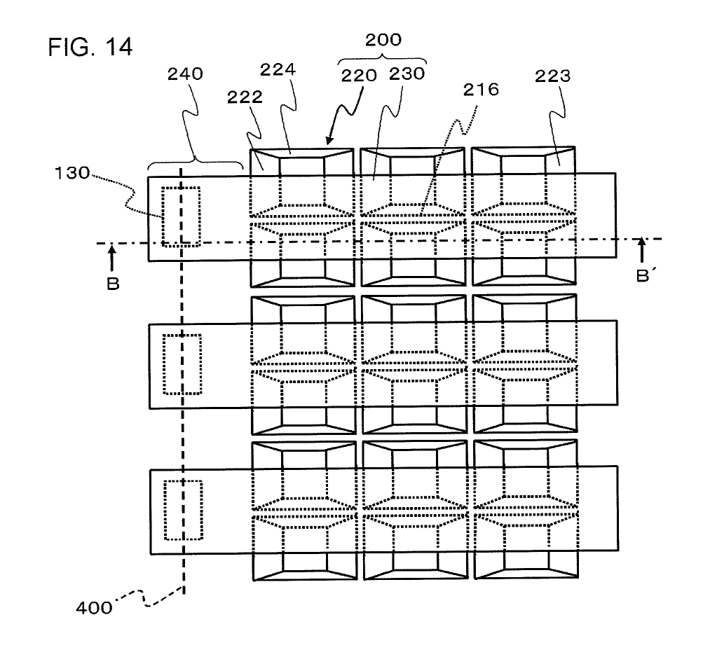

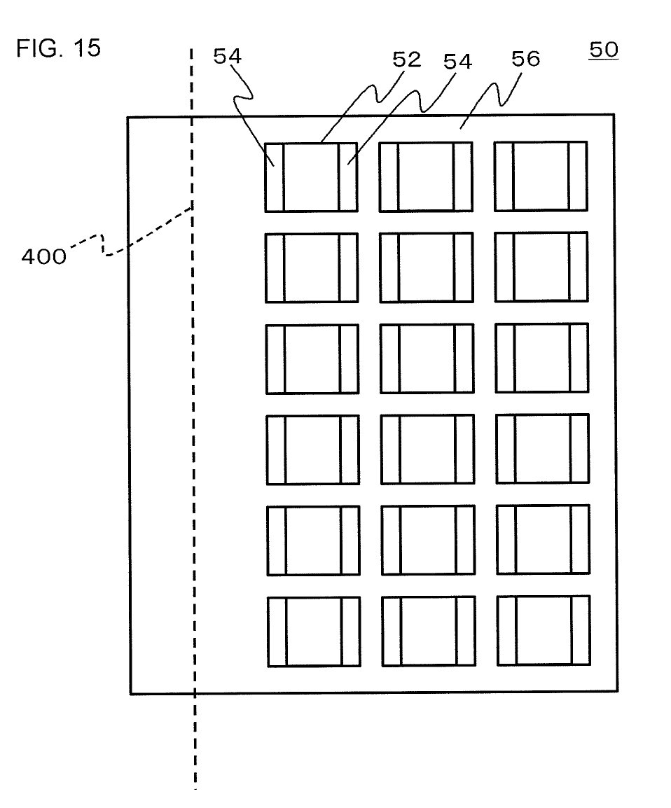

FIG. 14 is a plan view illustrating a configuration of the semiconductor device according to a seventh embodiment. FIG. 15 is a plan view illustrating a configuration of the multi-gradation mask 50 used in the manufacture of the semiconductor device of the embodiment. This semiconductor device has the same configuration as that of the semiconductor device according to the fifth embodiment, except that the groove 216 becomes further deeper and the bump core 220 is divided, and the cross-sectional view taken along the line B-B′ of FIG. 14 is the same as that of the fourth embodiment, that is, the same as FIG. 8A. A method of manufacturing of this semiconductor device is the same as the method of manufacturing the semiconductor device according to the fifth embodiment, except that the entire light-shielding region 56 instead of the semi-transmissive region 54 is provided in a region corresponding to the groove 216 in the multi-gradation mask 50, as shown in FIG. 15.

The same advantages as those of the fifth embodiment can also be obtained by the embodiment.

As described above, although the embodiments of the invention have been set forth with reference to the drawings, they are merely illustrative of the invention, and various configurations other than those stated above can be adopted. For example, in each of the embodiments mentioned above, although the multi-gradation mask 50 is set to three gradations consisting of the entire light-shielding region 52, the semi-transmissive region 54, and the entire-transmissive region 56, the semi-transmissive region 54 may be further set to a multi-gradation, and thus may be formed to have a continuous gradation.

It is apparent that the present invention is not limited to the above embodiments, but may be modified and changed without departing from the scope and spirit of the invention.

What is claimed is:

1. A method of manufacturing a semiconductor device, comprising:
forming a plurality of electrode pads in a substrate;
forming a protective insulating film having a plurality of openings located over each of said electrode pads in said plurality of electrode pads and the peripheries of said plurality of electrode pads;
forming a photosensitive resin film over said protective insulating film;
forming a plurality of bump cores over said protective insulating film along a first straight line, by exposing and developing said photosensitive resin film; and
forming a plurality of bumps, and a plurality of interconnects that connects each of said plurality of bumps to any of said electrode pads, by selectively forming conductive films over said plurality of bump cores, said plurality of electrode pads, and said protective insulating film,
wherein in said step of forming the plurality of bump cores, a region bordering on said interconnect on the lateral faces of said bump core is formed to have a gentler slope than a region intersecting said first straight line, by exposing said photosensitive resin film only one time using a multi-gradation mask.

2. The method of manufacturing the semiconductor device as set forth in claim 1,
wherein said photosensitive resin film is a positive type, and
wherein in said multi-gradation mask, the amount of light transmission of a portion corresponding to the region bordering on said interconnect on the lateral faces of said bump core is larger than the amount of light transmission of a portion corresponding to the region intersecting the first straight line on the lateral faces of said bump core.

3. The method of manufacturing the semiconductor device as set forth in claim 1,
wherein a distance between centers of said bump cores located next to each other is equal to or less than 50 μm.

4. The method of manufacturing the semiconductor device as set forth in claim 1,
wherein said photosensitive resin film is a phenol resin, an epoxy resin, a polyimide resin, an amino resin, an unsaturated polyester resin, a silicon resin, or an allyl resin.

5. The method of manufacturing the semiconductor device as set forth in claim 1,
wherein said plurality of bump cores is configured so that the lower portions of said plurality of bump cores are connected to each other.

6. A mask that exposes a photosensitive resin film, and forms bump cores of each of a plurality of bumps, comprising:
a plurality of patterns, provided along a first straight line, for forming the bump cores,
wherein said patterns are formed by combination of an entire light-shielding region that shields exposure light and an entire-transmissive region that transmits the exposure light, and
wherein the mask further comprises a semi-transmissive region that semi-transmits the exposure light, connected to a portion stretched in a direction that does not intersect the first straight line in the boundary of said entire light-shielding region and said entire-transmissive region.
